(19) United States
(12) Patent Application Publication
(10) Pub. No.: US 2024/0258269 A1
(43) Pub. Date: Aug. 1, 2024

(54) WAFER-LEVEL PACKAGING METHOD FOR SEMICONDUCTOR AND SEMICONDUCTOR PACKAGE

(71) Applicant: GALAXYCORE SHANGHAI LIMITED CORPORATION, Shanghai (CN)

(72) Inventor: Lixin Zhao, Shanghai (CN)

(21) Appl. No.: 17/255,015

(22) PCT Filed: Jun. 26, 2018
(86) PCT No.: PCT/CN2018/092885

§ 371 Date: May 26, 2021

(51) Int. Cl. H01L 23/00; H10B 80/00

(52) U.S. Cl. CPC H01L 24/94; H01L 24/08; H01L 24/80; H10B 80/00; H01L 2224/08145; H01L 2224/80895; H01L 2224/80896; H01L 2224/94

(57) ABSTRACT

Disclosed are a wafer-level packaging method for a semiconductor and a semiconductor package. The wafer-level packaging method for the semiconductor comprises: providing a first wafer having one or more memory chip units, each memory chip unit having a storage array circuit and a peripheral circuit, a first scribe line being provided between adjacent memory chip units; providing a second wafer having one or more logic chip units, an area of each logic chip unit corresponding to an area of N memory chip units, N being a natural number greater than or equal to one, a second scribe line being provided between adjacent logic chip units, the second scribe line matching the first scribe line at the periphery of the N memory chip units; and bonding the first wafer to the second wafer to enable the logic chip units to match with the N memory chip units correspondingly. The wafer-level packaging method for the semiconductor expands the application range of a package of a memory wafer.

### FIELD

The present invention relates to the field of semiconductor manufacturing, and particularly to a wafer-level packaging method for semiconductor and semiconductor package.

### BACKGROUND

There are many types of memories, such as Static Random Access Memory (SRAM), Dynamic Random Access Memory (DRAM), Flash Memory (FLASH), Phase Change Memory (PCM), etc. They are widely used in various electronic devices, and play an important role in the circuit.

A logic chip generally refers to a chip with a Programmable Logic Device (PLD). The logic chip has a high degree of integration sufficient to meet the needs of designing a general digital system.

At present, there are generally the following conventional manners of connecting a memory chip with a logic chip:
1. The dies of the memory chip and the logic chip are packaged separately, and the packaged ides are welded on the circuit board and connected to each other by wiring on the circuit board.
2. The dies of the memory chip and the logic chip are connected to each other by connecting wires to a substrate, and then packaged as a whole.
3. A micropad grows on die wafers (namely, a wafer including the logic chip unit and a wafer including the memory chip unit), the two chips are directly connected via the micropad, and then packaged as a whole.

Generally, as for the above three methods, the packaging performance becomes better, the consumed power is reduced, the volume becomes smaller and the cost is reduced from method 1 to method 3.

Regarding the first two packaging methods, there are generally dual in-line packaging, flat packaging, ball grid packaging, etc. These packaging methods require the wafer to be cut into dies which are then packaged separately. The wafer-level packaging method involves performing overall processing on the whole piece of wafer so that a tin ball grows, and then cutting it to obtain the duly-package chips. As compared with general packaging method, the wafer-level packaging method exhibits advantages such as lower costs, better uniformity and a smaller package volume.

Regarding the third packaging manner, a wafer-to-wafer packaging manner is provided. Specifically, two wafers of the same size are directly bonded. Each chip on the two wafers is of the same size, pins are arranged correspondingly, connection between all chips on the two wafers is completed after completion of the bonding, and the chips are packaged as a whole, outward pads are led out, and duly-connected separate chip groups are obtained after dicing.

The wafer-to-wafer packaging method completes connection of all chips on the two wafers simultaneously, without need to connect the two types of chips one by one as in the preceding two manners, so the costs get lower. Furthermore, since all chips are bonded and packaged simultaneously, the resultant products have better uniformity than the one-by-one packaging manner. However, the wafer-to-wafer packaging manner is currently applied to a very narrow scope of application.

To this end, it is desirable to provide a new wafer-level packaging method for semiconductor and semiconductor package, to expand the application scope of the wafer-to-wafer packaging method, improve flexibility of semiconductor packaging, simplify the packaging method, reduce waste of area when chips having different areas are packaged, and improve the application scope of the memory wafer packaging.

### SUMMARY

The problem solved by the present invention is to provide a wafer-level packaging method for a semiconductor and a semiconductor package to expand the application range of wafer-to-wafer packaging, improve the flexibility of semiconductor packaging, simplify the packaging method, and reduce waste of area when chips having different areas are packaged.

In order to solve the above problems, the present invention provides a wafer-level packaging method for a semiconductor, comprising:
providing a first wafer having one or more memory chip units, each memory chip unit having a storage array circuit and a peripheral circuit, a first scribe line being provided between adjacent memory chip units;
providing a second wafer having one or more logic chip units, each logic chip unit having an area corresponding to an area of N memory chip units, N being a natural number greater than or equal to one, a second scribe line being provided between adjacent logic chip units, the second scribe line matching the first scribe line at the periphery of the N memory chip units;
bonding the first wafer to the second wafer to enable the logic chip unit to match the corresponding N memory chip units.

Optionally, the step of bonding the first wafer to the second wafer comprises:
forming a first interfacing pad located on an upper surface of the first wafer;
forming a second interfacing pad located on an upper surface of the second wafer;
electrically bonding the first interfacing pad to the second interfacing pad.

Optionally, the step of bonding the first wafer to the second wafer comprises:
physically connecting the first wafer to the second wafer:
electrically coupling the logic chip units to the memory chip units via a through-silicon via process.

Optionally, the first interfacing pad is electrically connected to pads of a first multilayer metal layer inside the first wafer, and the pads of the first multilayer metal layer are electrically connected to a bus inside the first wafer: the second interfacing pad is electrically connected to pads of a second multilayer metal layer inside the second wafer, and the pads of the second multilayer metal layer are electrically connected to a bus inside the second wafer.

Optionally, the memory chip unit includes at least one type of SRAM, DRAM, FLASH, PCM, DDR, DDR2, DDR3 and DDR4.

Optionally, the peripheral circuit comprises: at least one type of a control logic circuit, an interface conversion logic circuit and an error correction code logic circuit.

Optionally, providing the first wafer further comprises:
forming a test circuit module in a region of the first scribe line.

Optionally, providing the second wafer further comprises:
forming a test circuit module in a region of the second scribe line.

Optionally, the method further comprises: after bonding the first wafer to the second wafer, grinding and thinning the first wafer and the second wafer.

In order to solve the above problems, the present invention provides a semiconductor package comprising:
a first wafer having one or more memory chip units, a first scribe line being between adjacent memory chip units;
a second wafer having one or more logic chip units, a second scribe line being between adjacent logic chip units, the logic chip unit having an area corresponding to an area of N memory chip units, where N is a natural number greater than or equal to one;
the first wafer is bonded to the second wafer, the logic chip unit corresponds to the N memory chip units, and the second scribe line matches the first scribe line at the periphery of the N memory chip units.

Compared to the prior art, the technical solution of the present invention has the following advantages:

In the technical solution of the present invention, a logic chip unit is designed to match corresponding N memory chip units, where N is a natural number greater than or equal to 1, so as to ensure that the two wafers can be directly bonded and packaged. When N is greater than 1, the area correspondence relationship between the two chip units can be fully utilized for matching, thereby reducing area waste and increasing the application scope of the packaging method of the memory wafers.

Further, a test circuit module is formed in the scribe line of the wafer. The test circuit module is formed in the first scribe line of the first wafer, and the test circuit module may be connected to the first interfacing pad to test the memory chip units, thereby improving the final packaging yield rate.

### BRIEF DESCRIPTION OF THE DRAWINGS

FIG. 1 is a schematic diagram of a first wafer provided by an embodiment of the present invention;

FIG. 2 is a structural schematic diagram of a memory chip in the first wafer shown in FIG. 1:

FIG. 3 is a schematic diagram of a second wafer provided by an embodiment of the present invention:

FIG. 4 is a schematic diagram in which the first wafer shown in FIG. 1 and the second wafer shown in FIG. 3 are arranged in alignment with each other before bonding:

FIG. 5 is a schematic diagram of a bonding arrangement of a first wafer and a second wafer provided by another embodiment of the present invention.

### DETAILED DESCRIPTION OF EMBODIMENTS

As mentioned in the Background, the wafer-to-wafer packaging method is currently applied to a very narrow scope of application. A type of memory wafers cannot be adapted for logic wafers of different sizes, and is generally only adapted for a type of logic wafers.

To this end, the present invention provides a new wafer-level packaging method for a semiconductor, which improves the application scope of the wafer-to-wafer packaging method and reduces waste of the chip area by matching one logic chip unit with more than one memory chip units

In order to make the above objectives, features and advantages of the present invention more apparent, specific embodiments of the present invention will be described in detail below with reference to the accompanying drawings.

An embodiment of the present invention provides a wafer-level packaging method for a semiconductor, as shown in FIG. 1 through FIG. 4.

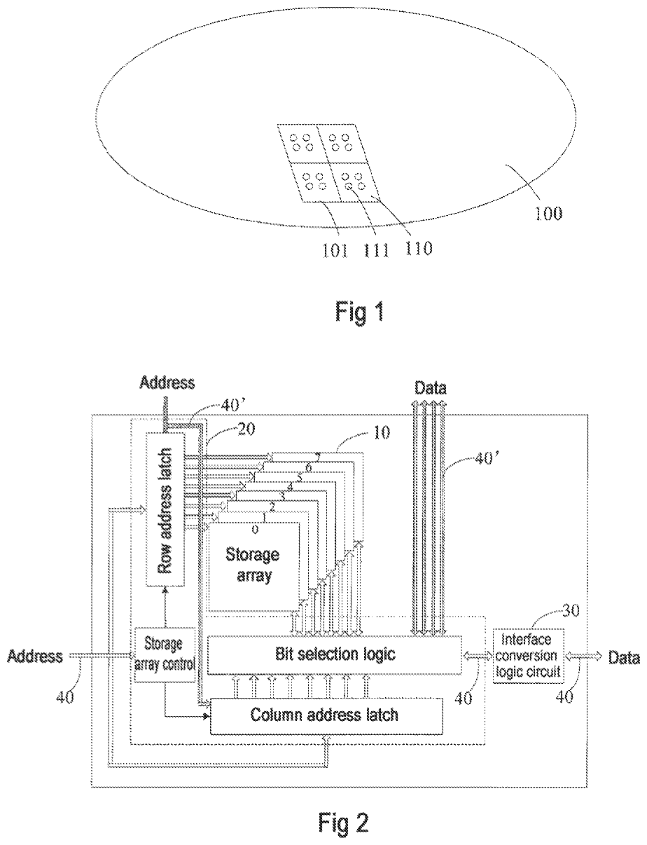

Referring to FIG. 1, a first wafer 100 having one or more memory chip units 110 is provided. FIG. 1 typically shows four memory chip units 110 arranged in a 2×2 matrix on the first wafer 100. Each memory chip unit 110 has a storage array circuit (referring to FIG. 2) and a peripheral circuit (not shown), and there is a first scribe line 101 between adjacent memory chip units 110.

The memory chip unit 110 may be at least one type of SRAM, DRAM, FLASH, PCM, DDR, DDR2, DDR3 and DDR4. In the present embodiment, the memory chip unit 110 specifically takes a DRAM as an example for description.

Referring to FIG. 2, the memory chip unit 110 may include a storage array 10, a control logic circuit 20, an interface conversion logic circuit 30, an original bus 40 (including an address bus and a data bus), and an ultra-wide bus 40′ (including an ultra-wide address bus and an ultra-wide data bus).

Further referring to FIG. 2, the storage array 10 includes 8 banks (bank0-bank7), each bank includes a plurality of storage cells, and the storage array 10 is used to store data.

Further referring to FIG. 2, the control logic circuit 20 includes: a row address latch, a storage array control (circuit), a column address latch, a bit selection logic (circuit), etc. The control logic circuit 20 is used to control the storage array 10 to implement read/wrote operation on specific storage cells in the banks.

The interface conversion logic circuit 30 is used to transmit the data read from the bank through a specific interface after serial-to-parallel conversion. The width of the data bus passing through the interface conversion logic circuit 30 will be greatly reduced.

Further referring to FIG. 2, the original bus 40 includes: an original address bus and an original data bus. The width of the original address bus is generally about 15 bits: the width of the original data bus is generally 4, 8, or 16 bits. In the present embodiment, the width of the original data bus before the serial-parallel conversion by the interface logic conversion circuit is 16 bits, and the width of the original data bus after the serial-parallel conversion by the interface logic conversion circuit is reduced to 4 bits. The original data bus after the serial-parallel conversion will finally be connected to a signal pad (not shown) to meet the needs of traditional DRAM packaging.

Further referring to FIG. 2, the ultra-wide bus 40′ includes an ultra-wide address bus and an ultra-wide data bus. The width of the ultra-wide bus 40′ is significantly larger than that of the original bus 40. Specifically, the ultra-wide address bus may be divided into multiple channels (for example, 2, 4 or 8 channels, etc., in the present embodiment, only one channel is shown), and each channel has a width of about 32 bits. The ultra-wide data bus may also be divided into multiple channels, and each channel has a width of 64, 128 or 256 bits, or even wider. In the present embodiment, the width of the ultra-wide data bus is 128 bits. The ultra-wide data bus does not pass through the interface conversion logic circuit 30, but is together with the ultra-wide address bus, directly connected to a micro pad (not shown) to realize the DRAM of the ultra-wide bus.

When the memory chip unit 110 is a DRAM, in order to ensure the reliability of the DRAM or improve the multiplexing rate, the internal bus of the memory chip unit 110 may be connected to multiple groups of storage arrays. The storage array may include a plurality of banks for storing data. The internal bus is a data bus and a control bus connected to the storage array and having a large width, and its data width may be greater than or equal to 64 bits. The internal bus is connected to at least one group of storage arrays.

Although not shown in FIG. 1 and FIG. 2, in the present embodiment, a first top metal layer (not shown) may be formed on the memory chip unit 110 of the DRAM, a power supply pad (not shown), a signal pad (not shown) and a micro pad (not shown) are formed on the first top metal layer, and the internal bus of the memory chip unit 110 is electrically connected to the micro pad.

The first wafer 100 provided in the present embodiment further includes a first interfacing pad 111 formed on the upper surface of the first wafer 100, as shown in FIG. The first interfacing pad 111 is electrically connected to the pads (including the power pad and signal pad, etc.) of a first multilayer metal layer inside the first wafer 100, and the pads of the first multilayer metal layer are electrically connected to the internal bus of the first wafer 100. Therefore, the first interfacing pad 111 is electrically connected to the internal bus of the first wafer 100.

The first interfacing pad 111 additionally formed in the present embodiment leads the wider internal bus to the surface of the DRAM. Each first interfacing 111 is at least connected to one of the internal buses. To ensure the reliability of the DRAM or improve the multiplexing rate, the first interfacing pad 111 may also be connected to multiple internal buses.

In the present embodiment, one or a first multilayer metal layer may be formed on the memory chip unit 110, and then the first interfacing pad 111 is formed in the top metal layer, as shown in FIG. 1. In addition, the wide internal bus is led out of the storage array of the memory chip unit 110 and electrically connected to the first interfacing pad 111.

The present embodiment still uses the power supply pad and signal pad in the conventional DRAM package. The power supply pad is used to power the DRAM, and the signal pad is used to implement DRAM reading through a traditional interface control logic circuit.

In the present embodiment, as described above, the peripheral circuit may include at least one of a control logic circuit, an interface conversion logic circuit, and an error correction code logic circuit. The control logic circuit includes a row address latch, a storage array control circuit, a column address latch, a bit selection logic circuit, etc., and is used to control the storage array to implement read/write operations on specific memory cells in the banks. The interface conversion logic circuit is used to transmit the data read from the bank through a specific interface after serial-to-parallel conversion. The width of the data bus passing through the interface conversion logic circuit will be greatly reduced.

It should be noted that in other embodiments of the present invention, the memory chip unit 110 may also be formed using the storage cells of one or more banks of a standard DRAM plus the peripheral circuit, or the memory chip unit 110 may also be formed using one or more blocks of a standard FLASH plus the peripheral circuit.

Although not shown in FIGS. 1 and 2, the first wafer 100 provided in the present embodiment may further include: a test circuit module formed in the region of the first scribe line 101. The test circuit module is formed in the first scribe line 101 of the first wafer 100, and the test circuit module may be connected to the first interfacing pad 111 to test the memory chip unit 110.

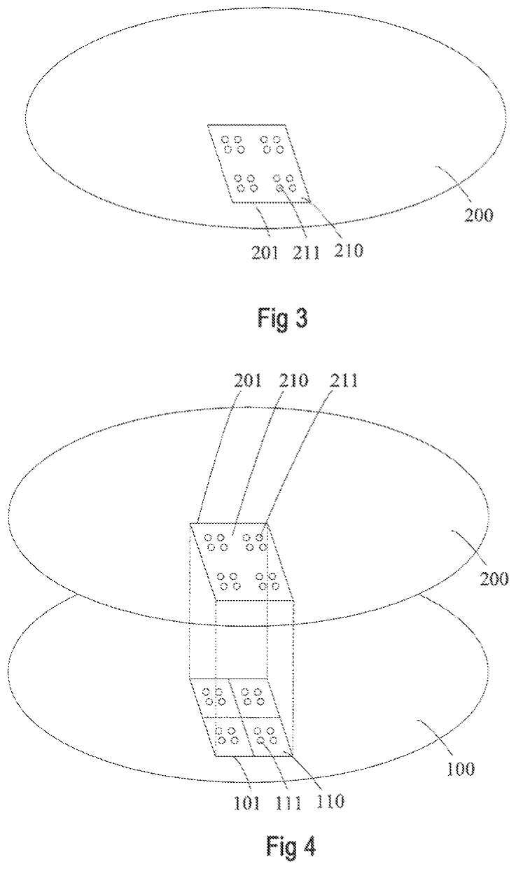

Referring to FIG. 3, a second wafer 200 having one or more logic chip units 210 is provided. FIG. 3 typically shows one of the logic chip units 210 of the second wafer 200.

In the present embodiment, the area of each logic chip unit 210 corresponds to the area of four memory chip units 110.

In the present embodiment, there is a second scribe line 201 between adjacent logic chip units 210, and the second scribe line 201 matches the first scribe line 101 on the periphery of the four memory chip units (please refer to the corresponding content in FIG. 4 later).

In the present embodiment, that the area of each logic chip unit 210 corresponds to that of the four memory chip units 110 means that the area of each logic chip unit 210 is substantially equal to that of the four memory chip units 110, and the area shape of the four memory chip units 110 is the same as that of each logic chip unit 210, and the first interfacing pad 111 on the four memory chip units 110 is positioned opposite to the second interfacing pad 211 on the logic chip unit 210. In this way, it is ensured that the first interfacing pad 111 of a subsequent logic chip unit 210 can be electrically connected to the second interfacings 211 of the four memory chip units 110 to form a bonding structure.

The application scope of the conventional wafer-to-wafer packaging is still very narrow: One of the main reasons is: wafer-to-wafer packaging requires the chips on the two wafers to be docked to have the same size, whereas the logic wafer and the memory wafer are generally produced by different manufacturers, and their sizes are generally different. If the two are to be made have same size, filling small chips to enlarge the chip area will cause waste. Furthermore, the sizes of logic wafers of different designs vary greatly. A type of memory wafer cannot be adapted for logic wafers of different sizes, and are generally only adapted for one logic wafer.

In the embodiment of the present invention, one logic chip unit may correspond to one or more than one memory chip unit, which expands the application range of wafer-to-wafer packaging, reduces waste of the area, and improves the application range of the memory wafers.

It needs to be appreciated that in other embodiments of the present invention, the area of each logic chip unit 210 may also correspond to the area of 1, 2, 3, or more than 5 memory chip units 110, and this is not limited herein in the present invention. That is, the area of each logic chip unit 210 may correspond to the area of N memory chip units 110, where N is a natural number greater than or equal to 1.

In the present embodiment, the upper surface of the second wafer 200 provided is further provided a second interfacing pad 211 located on the surface of the logic chip unit 210. The second interfacing pad 211 is electrically connected to the pads of the second multilayer metal layer inside the second wafer 200, and the pads of the second multilayer metal layer are electrically connected to the internal bus of the second wafer 200. The process of forming the second interfacing pad 211 is similar to the process of forming the first interfacing pad 111, and reference may be made to the above corresponding content.

In the present embodiment, the second interfacing pad 211 is positioned corresponding to the first interfacing pad 111, so as to ensure that the subsequent logic chip unit 210 can match the memory chip unit 110.

The first wafer 100 provided in the present embodiment further includes: a test circuit module formed in the region of the second scribe line 201. The test circuit module is formed in the second scribe line 201 of the second wafer 200. The test circuit module may be connected to the second interfacing pad 211 to test the logic chip unit 210, thereby improving the final packaging yield rate.

It should be appreciated that the provided first wafer 100 and second wafer 200 may be repaired. The present invention does not specifically limit the method for repairing wafers. There are various methods for repairing wafers in the prior art, such as laser trimming, etc., which all may be applied to the present invention. Through repair, the yield rate of the first wafer 100 may be further improved.

Referring to FIG. 4, the first wafer 100 is bonded to the second wafer 200 so that the logic chip unit 210 matches the four memory chip units 110 correspondingly.

FIG. 4 shows a moment before the first wafer 100 and the second wafer 200 are bonded (i.e., a situation where the two wafers are aligned with each other).

In the present embodiment, the first scribe line 101 on the periphery of the assembly of the four memory chip units 110 corresponds to the second scribe line 201 of one logic chip unit 210 (as intuitively adjusted according to the four unmarked dashed lines in FIG. 4), thereby ensuring that one logic chip unit 210 matches the four memory chip units 110 correspondingly. Furthermore, as mentioned above, the first interfacing pad 111 of the four memory chip units 110 corresponds to the second interfacing pad 211 of one logic chip unit 210. Therefore, when the first wafer 100 is bonded to the second wafer 200, the first interfacing pad 111 is electrically bonded to the second interfacing pad 211.

In the present embodiment, after the first wafer 100 is bonded to the second wafer 200, at least one of the first wafer 100 and the second wafer 200 may be ground and thinned. Generally, the thickness used by the logic circuit and a metal wiring portion in the wafer is about 100 μm, but the overall thickness of the wafer is about 1000 μm to provide better support. As for the bonded wafers, the logic circuit portion and the metal wiring portion are at an intermediate position of the two wafers. At this time, a too large wafer thickness does not facilitate heat dissipation, and reduction of the wafer thickness may improve the heat dissipation effect, so that the finally-obtained assembly has a small thickness and an improved heat dissipation performance.

In the present embodiment, after the first wafer 100 is bonded to the second wafer 200, the wafer may be subsequently diced to form individual chip combinations (each chip combination includes one logic chip unit 210 and four memory chip units 110, and they are electrically bonded), and each chip combination is encapsulated.

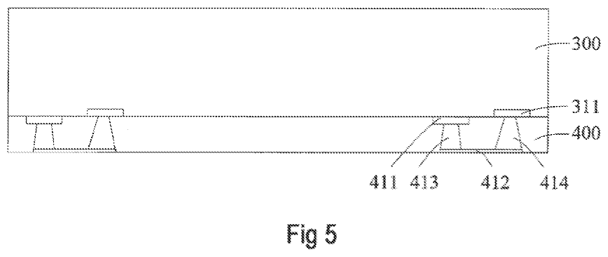

Another embodiment of the present invention provides another wafer-level packaging method for a semiconductor, as shown in FIG. 5.

Referring to FIG. 5, a first wafer 300 having one or more memory chip units (not shown) is provided. Each memory chip unit has a storage array circuit and a peripheral circuit, and there is a first scribe line (not shown) between adjacent memory chip units.

The memory chip unit may be at least one type of SRAM, DRAM, FLASH, PCM, DDR, DDR2, DDR3, and DDR4. In the present embodiment, the memory chip unit is specifically described with DRAM as an example.

Specifically, the memory chip unit includes: a storage array, a control logic circuit, an interface conversion logic circuit, an original bus and an ultra-wide bus.

The first wafer 300 provided in the present embodiment further includes a first interfacing pad 311 formed on the upper surface of the first wafer 300. The first interfacing pad 311 is electrically connected to the pads (including the power pad and signal pad, etc.) of a first multilayer metal layer inside the first wafer 100, and the pads of the first multilayer metal layer are electrically connected to the internal bus of the first wafer 300.

In the present embodiment, one or a first multilayer metal layer may be formed on the memory chip unit, and then the first interfacing pad 311 is formed in the top metal layer. Furthermore, the wide internal bus is led out of the storage array of the memory chip unit 110 and electrically connected to the first interfacing pad 311.

In the present embodiment, the peripheral circuit may include at least one of a control logic circuit, an interface conversion logic circuit, and an error correction code logic circuit. The control logic circuit includes a row address latch, a storage array control circuit, a column address latch, a bit selection logic circuit, etc.

The first wafer 300 provided in the present embodiment further includes: a test circuit module formed in the region of the first scribe line. The test circuit module is formed in the first scribe line of the first wafer 300, and the test circuit module may be connected to the first interfacing pad 311 to test the memory chip unit to improve the final packaging yield rate.

Further referring to FIG. 5, a second wafer 400 having one or more logic chip units 210 is provided. The area of each logic chip unit corresponds to the area of a plurality of memory chip units. There is a second scribe line (not shown) between adjacent logic chip units, and the second scribe line matches the first scribe line on the periphery of the plurality of memory chip units. Reference may be made to the corresponding content in the preceding embodiment.

In the present embodiment, that the area of each logic chip unit corresponds to that of the plurality of memory chip units means that the area of each logic chip unit is substantially equal to that of the plurality of memory chip units, and the area shape of the plurality of memory chip units is the same as that of each logic chip unit, and the first interfacing pad on the plurality of memory chip units is positioned opposite to the second interfacing pad 411 on the logic chip unit. In this way, it is ensured that the first interfacing pad 311 of a subsequent logic chip unit can be electrically connected to the second interfacings 411 of the plurality of memory chip units to form a bonding structure.

Further referring to FIG. 5, the surface of the second wafer 400 provided is provided with the second interfacing pad 411. The process of forming the second interfacing pad 411 is similar to the process of forming the first interfacing pad 311, and reference may be made to the above corresponding content.

The second interfacing pad 411 is electrically connected to the pads of the second multilayer metal layer inside the second wafer 400, and the pads of the second multilayer metal layer are electrically connected to the internal bus of the second wafer 400.

The first wafer 300 provided in the present embodiment further includes: a test circuit module formed in the region of the second scribe line. The test circuit module is formed in the second scribe line of the second wafer. The test circuit module may be connected to the second interfacing pad 411 to test the logic chip unit, thereby improving the final packaging yield rate.

Referring to FIG. 5, different from the foregoing embodiment, in the present embodiment, when the first wafer 300 is bonded to the second wafer 400, the first wafer 300 is physically connected to the second wafer 400. In the present embodiment, the two are specifically overlapped, so that the logic chip unit matches the plurality of memory chip units correspondingly.

Further referring to FIG. 5, the step of bonding the first wafer 300 to the second wafer 400 further includes: electrically coupling the logic chip unit to the memory chip unit through a through-silicon via process. In FIG. 5, it is shown that after the first wafer 300 and the second wafer 400 are stacked together, a through-silicon via structure 413 is formed in the second wafer 400 to electrically connect the second interfacing pad 411, and the other end of the through-silicon via structure 413 is electrically connected to the metal layer 412. Meanwhile, a through-silicon via structure 414 is also made in the second wafer 400 to electrically connect with the first interfacing pad 311, and the other end of the through-silicon via structure 413 is also electrically connected to the metal layer 412. Therefore, the first interfacing pad 311 is electrically connected with the second interfacing pad 411 through the through-silicon via structure 414, the metal layer 412, and the through-silicon via structure 413.

In the present embodiment, operations such as wafer thinning, wafer dicing and chip encapsulation may also be subsequently performed, which will not be repeated here.

According to the wafer-level packaging method for semiconductor provided in the present embodiment, wafer-level packaging can be flexibly performed for the logic chip and memory chips, the operations are simpler and the process costs are low.

A further embodiment of the present invention further provides a semiconductor package. Specifically, the semiconductor package includes: a first wafer having one or more memory chip units, a first scribe line being between adjacent memory chip units: a second wafer having one or more logic chip units, a second scribe line being between adjacent logic chip units, an area of the logic chip unit corresponding to an area of N memory chip units, where N is a natural number greater than or equal to one: the first wafer is bonded to the second wafer, the logic chip units correspond to the N memory chip units, and the second scribe line matches the first scribe line at the periphery of the N memory chip units. The semiconductor package may be formed by the wafer-level packaging method of the preceding embodiments. Hence, reference may be made to the corresponding content in the preceding embodiments for the structure and property of the semiconductor package.

Although the present invention is disclosed as above, the present invention is not limited thereto. Any person skilled in the art may make various changes and modifications without departing from the spirit and scope of the present invention. Therefore, the protection scope of the present invention should be subject to the scope defined by the appended claims.

I/We claim:

1. A wafer-level packaging method for semiconductor comprising:
providing a first wafer having one or more memory chip units, each memory chip unit having a storage array circuit and a peripheral circuit, a first scribe line being provided between adjacent memory chip units;
providing a second wafer having one or more logic chip units, each logic chip unit having an area corresponding to an area of N memory chip units, N being a natural number greater than or equal to one, a second scribe line being provided between adjacent logic chip units, the second scribe line matching the first scribe line at the periphery of the N memory chip units;
bonding the first wafer to the second wafer to enable the logic chip unit to match the corresponding N memory chip units.

2. The wafer-level packaging method for a semiconductor according to claim 1, wherein the step of bonding the first wafer to the second wafer comprises:
forming a first interfacing pad located on an upper surface of the first wafer;
forming a second interfacing pad located on an upper surface of the second wafer;
electrically bonding the first interfacing pad to the second interfacing pad.

3. The wafer-level packaging method for a semiconductor according to claim 1, wherein the step of bonding the first wafer to the second wafer comprises:
physically connecting the first wafer to the second wafer;
electrically coupling the logic chip units to the memory chip units via a through-silicon via process.

4. The wafer-level packaging method for a semiconductor according to claim 2, wherein the first interfacing pad is electrically connected to pads of a first multilayer metal layer inside the first wafer, and the pads of the first multilayer metal layer are electrically connected to a bus inside the first wafer; the second interfacing pad is electrically connected to pads of a second multilayer metal layer inside the second wafer, and the pads of the second multilayer metal layer are electrically connected to a bus inside the second wafer.

5. The wafer-level packaging method for a semiconductor according to claim 1, wherein the memory chip unit includes at least one type of SRAM, DRAM, FLASH, PCM, DDR, DDR2, DDR3 and DDR4.

6. The wafer-level packaging method for a semiconductor according to claim 1, wherein the peripheral circuit comprises: at least one type of a control logic circuit, an interface conversion logic circuit and an error correction code logic circuit.

7. The wafer-level packaging method for a semiconductor according to claim 1, wherein providing the first wafer further comprises:
forming a test circuit module in a region of the first scribe line.

8. The wafer-level packaging method for a semiconductor according to claim 1, wherein providing the second wafer further comprises:
forming a test circuit module in a region of the second scribe line.

9. The wafer-level packaging method for a semiconductor according to claim 1, wherein the method further comprises: after bonding the first wafer to the second wafer, grinding and thinning the first wafer and the second wafer.

10. A semiconductor package comprising:
a first wafer having one or more memory chip units, a first scribe line being between adjacent memory chip units;
a second wafer having one or more logic chip units, a second scribe line being between adjacent logic chip units, the logic chip unit having an area corresponding to an area of N memory chip units, where N is a natural number greater than or equal to one;
the first wafer is bonded to the second wafer, the logic chip unit corresponds to the N memory chip units, and the second scribe line matches the first scribe line at the periphery of the N memory chip units.
